(19) United States
(12) Patent Application Publication
(10) Pub. No.: US 2016/0036945 A1
(43) Pub. Date: Feb. 4, 2016

(54) SIGNAL TRANSMISSION

(71) Applicant: NOKIA CORPORATION, Espoo (FI)

(72) Inventors: Joni Kristian PAJARINEN, VANTAA (FI); Jaakko Tapani PELTONEN, Espoo (FI); Ari Tapani HOTTINEN, Espoo (FI)

(21) Appl. No.: 14/781,394

(22) PCT Filed: Apr. 16, 2013
(86) PCT No.: PCT/FI2013/050415

§ 371 Date: Sep. 30, 2015

(51) Int. Cl. H04L 29/06; H03M 7/30

(52) U.S. Cl. CPC H04L 69/04; H03M 7/30

(57) ABSTRACT

An approach for bandwidth-efficient transmission of signals is provided, e.g. as an apparatus, as a method or as a computer program. According to an example embodiment, the approach comprising storing, in one or more data buffers, information descriptive of data transmitted from respective one or more data sources to a destination, identifying reference data in said one or more data buffers on basis of data to be transmitted by an apparatus and on basis of information stored in said one or more data buffers, determining residual data descriptive of the data to be transmitted by the apparatus in relation to the said reference data, and transmitting the residual data to the destination.

### TECHNICAL FIELD

The example and non-limiting embodiments of the present invention relate to transmission signals. In particular, at least some example embodiments relate to a method, an apparatus, and a computer program for bandwidth-efficient transmission of data from a sender to a receiver.

### BACKGROUND

This section is intended to provide a background or context to the invention that is recited in the claims. The description herein may include concepts that could be pursued, but are not necessarily ones that have been previously conceived, implemented or described. Therefore, unless otherwise indicated herein, what is described in this section is not prior art to the description and claims in this application and is not admitted to be prior art by inclusion in this section.

In many communication systems, especially in wireless ones, an efficient usage of transmission bandwidth plays an important role in feasibility and success of the communication system. While the development of radio transmission technologies during the past decades has resulted in major improvements in spectrum efficiency and hence enabled increased data rates over wireless links, increase in number of users and volume of the data transmitted/received per user continues to keep the efficient use of radio transmission resources an important aspect.

Compression of data prior to transmission over a link and decompression upon reception is one known technique that may be employed to facilitate efficient usage of transmission resources. In this regard, generic compression techniques such as deflate (RFC 1951) may be applied to provide lossless compression of data. As another example, a number of tailored media compression techniques are available for compression of e.g. speech, audio and video signals. Such media compression techniques typically apply lossy compression, implying that some of the information of the source signal can be omitted without affecting the perceptual quality of the media data. These compression techniques typically further make use of the fact that the media data typically includes some level of redundant information that can be efficiently compressed prior to transmission over a link, followed by decompression upon reception. However, while the above-mentioned techniques apply compression within a given data stream, they fail to address possible similarities between separate data streams.

### SUMMARY

It is therefore an object of the present invention to provide a technique that enables more bandwidth-efficient transmission of data from a sender to a receiver.

According to an example embodiment, an apparatus is provided, the apparatus comprising a data collection portion configured to store, in one or more data buffers, information descriptive of data transmitted from respective one or more data sources to a destination, a data comparison portion configured to identify reference data in said one or more data buffers on basis of data to be transmitted by the apparatus and on basis of information stored in said one or more data buffers, a data reduction portion configured to determine residual data descriptive of the data to be transmitted by the apparatus in relation to the said reference data, and a data transmission portion configured to transmit the residual data to the destination.

According to another example embodiment, an apparatus is provided, the apparatus comprising at least one processor and at least one memory including computer program code for one or more programs, the at least one memory and the computer program code configured to, with the at least one processor, cause the apparatus at least to store, in one or more data buffers, information descriptive of data transmitted from respective one or more data sources to a destination, to identify reference data in said one or more data buffers on basis of data to be transmitted by the apparatus and on basis of information stored in said one or more data buffers, to determine residual data descriptive of the data to be transmitted by the apparatus in relation to the said reference data, and to transmit the residual data to the destination.

According to another example embodiment, an apparatus is provided, the apparatus comprising means for storing, in one or more data buffers, information descriptive of data transmitted from respective one or more data sources to a destination, means for identifying reference data in said one or more data buffers on basis of data to be transmitted by the apparatus and on basis of information stored in said one or more data buffers, means for determining residual data descriptive of the data to be transmitted by the apparatus in relation to the said reference data, and means for transmitting the residual data to the destination.

According to another example embodiment, a method is provided, the method comprising storing, in one or more data buffers, information descriptive of data transmitted from respective one or more data sources to a destination, identifying reference data in said one or more data buffers on basis of data to be transmitted by an apparatus and on basis of information stored in said one or more data buffers, determining residual data descriptive of the data to be transmitted by the apparatus in relation to the said reference data, and transmitting the residual data to the destination.

According to another example embodiment, a computer program is provided, the computer program including one or more sequences of one or more instructions which, when executed by one or more processors, cause an apparatus at least to store, in one or more data buffers, information descriptive of data transmitted from respective one or more data sources to a destination, identify reference data in said one or more data buffers on basis of data to be transmitted by the apparatus and on basis of information stored in said one or more data buffers, determine residual data descriptive of the data to be transmitted by the apparatus in relation to the said reference data, and transmit the residual data to the destination.

The computer program may be embodied on a volatile or a non-volatile computer-readable record medium, for example as a computer program product comprising at least one computer readable non-transitory medium having program code stored thereon, the program which when executed by an apparatus cause the apparatus at least to perform the operations described hereinbefore for the computer program according to an example embodiment.

The exemplifying embodiments of the invention presented in this patent application are not to be interpreted to pose limitations to the applicability of the appended claims. The verb “to comprise” and its derivatives are used in this patent application as an open limitation that does not exclude the existence of also unrecited features. The features described hereinafter are mutually freely combinable unless explicitly stated otherwise.

Some features of the invention are set forth in the appended claims. Aspects of the invention, however, both as to its construction and its method of operation, together with additional objects and advantages thereof, will be best understood from the following description of some example embodiments when read in connection with the accompanying drawings.

### BRIEF DESCRIPTION OF FIGURES

Some embodiments of the invention are illustrated by way of example, and not by way of limitation, in the figures of the accompanying drawings.

FIG. 1 schematically illustrates an exemplifying arrangement according to an example embodiment.

FIG. 2a illustrates a method according to an example embodiment.

FIG. 2b illustrates a method according to an example embodiment.

FIG. 3 schematically illustrates a data sender according to an example embodiment.

FIG. 4 schematically illustrates a data sender and a data receiver according to an example embodiment.

FIG. 5 schematically illustrates an exemplifying apparatus in accordance with an example embodiment.

### DESCRIPTION OF SOME EMBODIMENTS

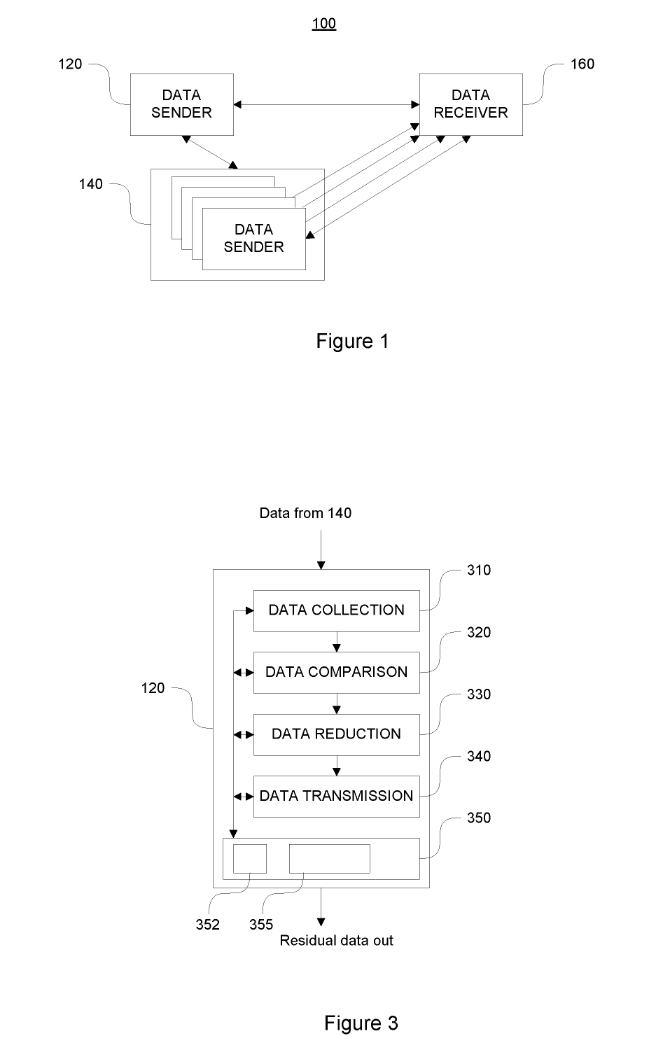

FIG. 1 schematically illustrates an exemplifying arrangement 100 comprising a first data sender 120, one or more second data senders 140 and a data receiver 160. The first data sender 120 is able to communicate with the data receiver 160 via a wireless and/or a wired network by transmitting and/or receiving data and signaling information. Hence, although the entity 120 is herein termed a data sender, it is typically also able to receive data and signaling information, e.g. from the data receiver 160 and/or from one or more second data senders 140. Similarly, a second data senders 140 is typically also able to receive data and signaling information, e.g. from the data receiver 160, from the first data sender 120 and/or from one or more of the other second data senders 140. Further along similar lines, the data receiver 160 is typically able to also send data and signaling information, e.g. to the first and second data senders 120, 140 and to further senders/receivers.

In an example embodiment, the data senders 120, 140 may or may not be configured to employ two-way communication with each other. However, a given data sender 120, 140 is, preferably, configured or enabled to receive communication, e.g. data and/or signaling information originating from the other data senders 120, 140. This communication may be primarily destined to the data receiver 160, but the given data sender 120, 140 may be nevertheless able to observe and/or to intercept the communication from the other data senders 120, 140 primarily intended for the data receiver 160. The data receiver 160 may be the final destination of the data originating from the data senders 120, 140. As another example, the data receiver 160 may serve an intermediate node that forwards the communication received from the data senders 120, 140 towards their final destination. The first data sender 120 and the second data senders 140 are, typically, operated in relatively close proximity with each other to enable the first data sender 120 to observe and/or intercept communication from the second data senders 140 to the data receiver 160.

For brevity and clarity of description and terminology, in this document a data sender 120, 140 may be also referred to as a data source or a source, whereas the data receiver 160 may be also referred to as a data destination or a destination.

The first data sender 120 and the one or more second data senders 140 may be able to communicate with each other and with the data receiver 160, for example, via a cellular mobile network by using respective cellular protocols known in the art, such as GSM, UMTS, LTE, CDMA, CDMA2000, etc. As another example, additionally or alternatively, the data senders 120, 140 may be able to communicate with each other and the data receiver 160 via a packet switched network, such as a local area network (LAN), a wireless local area network (WLAN), the Internet, etc. As a further example, additionally or alternatively, the data senders 120, 140 may be able to communicate with each other and with the data receiver 160 over a link of other type, e.g. by using BLUETOOTH (BT) technology or by using any other suitable communication means known in the art. Hence, the data senders 120, 140 are able to communicate with the data receiver 160 and with each other via a wireless and/or a wired network.

The network connecting a data sender 120, 140 to the data receiver 160 typically comprises a number of intermediate components, elements and/or apparatuses. Moreover, a data sender 120, 140 may be configured or enabled to communicate with the data receiver 160 over two or more networks of different type, either sequentially or concurrently. However, the details of the network are not described herein since the details of the network architecture or the role and operation of possible intermediate network components/elements/apparatuses does not play a significant role in the general operation of embodiments of the present invention.

The example arrangement 100 provides a logical framework, components of which, i.e. the data senders 120, 140 and the data receiver 160, may be embodied using one or more apparatuses. In particular, each of the components may be embodied by one or more apparatuses or as part of one or more apparatuses. However, typically, each data sender 120, 140 is embodied as a single apparatus or as a portion of a single apparatus. In an example embodiment, a data sender 120, 140 may be embodied as a mobile device or as a portion thereof, wherein the mobile device is a mobile phone, a smartphone, a gaming device, a personal assistant, a music player, a tablet computer, a laptop computer, etc. In an example embodiment, the data receiver 160 may be embodied as a single server apparatus, as one or more portions of a server apparatus, as a plurality of server apparatuses or as one or more portions of one or more server apparatuses. Each/any of the data senders 120, 140 and the data receiver 160 may be embodied in an apparatus by software means, by hardware means, or by a combination of software means and hardware means.

According to an example embodiment of the exemplifying arrangement 100, each of the data senders 120, 140 comprises a mobile transmitter of a cellular communication system in accordance with a cellular communication standard and the data receiver 160 comprises a base transceiver station or a base station controller of the cellular communication system in accordance with said cellular communication standard or another entity of the cellular (radio) access network.

According to another example embodiment of the exemplifying arrangement 100, the data senders 120, 140 comprise WLAN transmitters in accordance with an IEEE 802.11 standard and the data receiver 160 comprises a WLAN access point according to the respective standard or another element of the access network.

In accordance with example embodiments, the transmitted data may comprise any data that is simultaneously or essentially simultaneously accessed, extracted or captured by two or more data senders 120, 140. As an example of such data, the transmitted data may comprise sensory data originating of a plurality of sensors arranged to capture sensory information from the same space or location. Such sensors may comprise e.g. a plurality of proximity sensors such as passive infrared (PIR) sensors, a plurality of temperature sensors such as thermistors, a plurality of photosensors such as photoresistors or photodiodes, etc. The signal originating from the plurality of sensors may be processed and/or formatted for transmission to the data receiver 160 according to predetermined rule or protocol.

As another example of such data, the transmitted data may comprise media data originating from a source accessible by the first data sender 120 and the one or more second data senders 140 or data derived on basis of such media data. As a particular example in this regard, the media data may be audio data captured by the first data sender 120 and the one or more second data senders 140 at a location that is in proximity of the source of an audio signal, which audio data is processed at the respective data senders 120, 140 and transmitted to the data receiver 160. The processing of the audio data typically comprises converting captured audio data into digital format, segmenting audio data into a plurality of successive audio data blocks of desired length or duration and encapsulating the audio data blocks for transmission to the data receiver 160 in accordance with the applied communication scheme or system. Additionally, the processing may comprise encoding the plurality of audio data blocks before encapsulation for transmission e.g. by using an audio coding technique or a speech coding technique known in the art. In such a scenario the audio data blocks transmitted by the data senders 120, 140 typically exhibit similarities that may be exploited to facilitate efficient usage of transmission capacity in accordance with various embodiments.

As another example of the media data, the media data may be video data captured by the first data sender 120 and the one or more second data senders 140 at location relatively close to each other. In case the data senders 120, 140 are providing video data that is depicting a view that is the same or closely related, e.g. depicting a relatively remote object or view in angles that are relatively close to each other, the video data streams originating from the senders 120, 140 typically bear high level of similarity to each other that may be exploited to facilitate efficient usage of transmission capacity in accordance with various embodiments. The processing of the video data typically comprises arranging the captured images of the video stream into a sequence of image frames and encapsulating the video frames for transmission to the data receiver 160 in accordance with the applied communication scheme or system. Additionally, the processing may comprise encoding the captured video images into image frames e.g. by using a video coding technique known in the art.

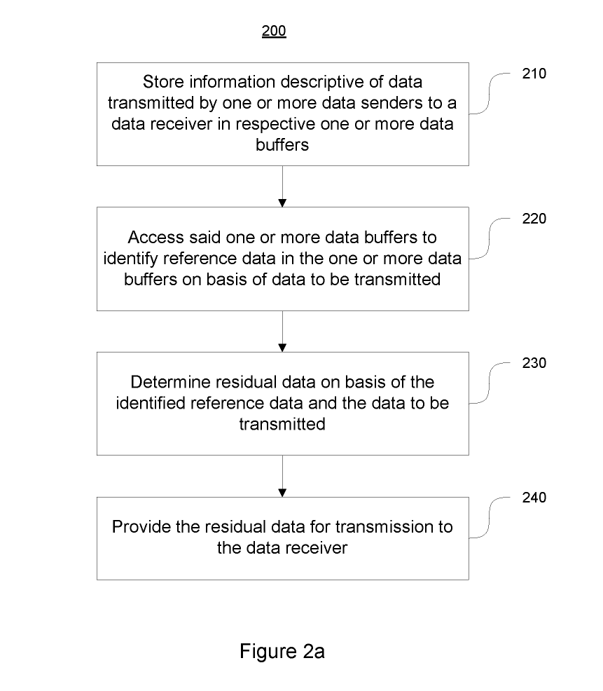

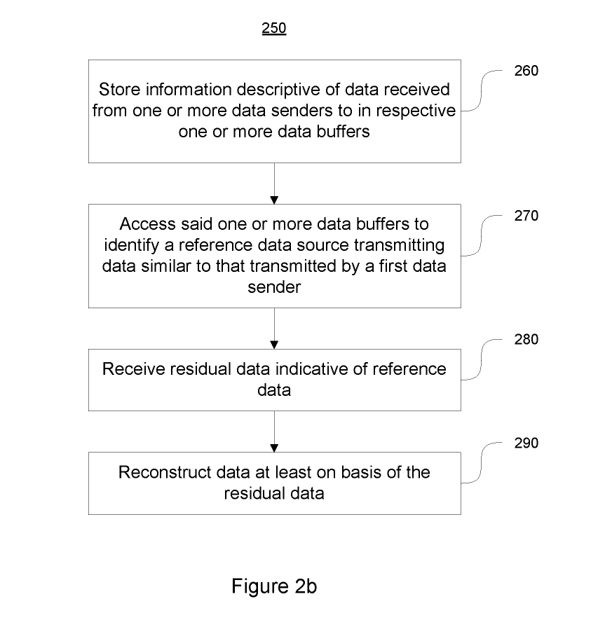

According to various example embodiments, one or more data senders 120, 140 may be transferring data in accordance with an exemplifying method 200 illustrated in FIG. 2a. The method 200 may comprise storing information descriptive of data transmitted by one or more data senders 120, 140 to the data receiver 160 in respective one or more data buffers, as indicated in block 210. Storing may comprise the first data sender 120 storing the data in respective data buffers. Further details applicable e.g. in context of block 210 are provided hereinafter in context of examples describing storing the data transmitted by the data senders 120, 140 in the respective data buffers in the first data sender 120 and/or in the data receiver 160.

The method 200 may further comprise accessing, e.g. searching, said one or data more buffers in order to identify reference data on basis of the data sent or to be send by the first data sender 120 and on basis of the data transmitted by one or more second data senders 140, as indicated in block 220. The search in the data buffers may be carried out in the first data sender 120 and/or in the data receiver 160. The reference data may be, for example, a segment of data transmitted by one of second data senders 140 that is found to be similar to the data to be transmitted by the first data sender 120. Accessing the one or more data buffers may comprise searching the one or more data buffers in order to determine a reference second data sender 140, i.e. a reference source, that is transmitting or has transmitted data that is similar to the data (to be) transmitted by the first data sender 120 and, consequently, identification of the reference data may comprise identifying, e.g. searching, the reference data in the data buffer corresponding to the reference source. Further details applicable e.g. in context of block 220 are provided hereinafter in context of examples describing accessing the data buffers in the first data sender 120 and/or in the data receiver 160.

The method 200 may further comprise determining and/or constructing residual data descriptive of the data to be transmitted by the first data sender 120 in relation to the reference data or a portion thereof, as indicated in block 230. The residual data may comprise, for example, an indication of the reference data in the data buffers accessible by the first data sender 120 and possibly the difference data between the data to be transmitted from the first data sender 120 and the reference data. Further details applicable e.g. in context of block 230 are provided hereinafter in context of examples describing determination of the residual data.

The method 200 may further comprise providing the residual data for transmission from the first data sender 120 to the data receiver 160, as indicated in block 240. Providing the residual data for transmission may comprise e.g. passing the residual data to a transmitter portion provided at or accessible by the first data source 120 and/or storing the residual data into the memory 350 for subsequent access by the transmitter portion.

According to various example embodiments, the data receiver 160 may be receiving data from one or more data senders 120, 140 in accordance with an exemplifying method 250 illustrated in FIG. 2b. The method 250 may comprise storing information descriptive of data received from the one or more data senders 120, 140 in respective one or more data buffers, as indicated in block 260. Further details applicable e.g. in context of block 260 are provided hereinafter in context of examples describing storing the data transmitted by the data senders 120, 140 in the respective data buffers in the first data sender 120 and/or in the data receiver 160.

The method 250 may further comprise accessing, e.g. searching, said one or data more buffers in order to identify a reference second data sender 140, i.e. a reference source, that is transmitting or has transmitted data that is similar to the data transmitted by the first data sender 120. The reference source may be, for example, the data source/sender that is found to provide data that is most similar to the data to be transmitted by the first data sender 120. Further details applicable e.g. in context of block 270 are provided hereinafter in context of examples describing accessing the data buffers in the first data sender 120 and/or in the data receiver 160.

The method 250 may further comprise receiving residual data, as indicated in block 280. The residual data is data that is descriptive of the data transmitted by the first data sender 120 in relation to the reference data or a portion thereof. The residual data may comprise, for example, an indication of the reference data in the data buffers accessible by the data receiver 160 and possibly the difference data between the data to be transmitted from the first data sender 120 and the reference data. The method 250 may further comprise reconstructing the data at least on basis of the residual data, as indicated in block 290. The reconstruction may comprise, for example, obtaining the reference data from the data buffer(s) accessible by the data receiver 160 and reconstructing the data on basis of the obtained reference data. The reconstruction may be further based on the received difference data, e.g. the reconstructed data may be obtained as a sum of the respective elements of the reference data and the difference data. Further details applicable e.g. in context of blocks 280 and/or 290 are provided hereinafter in context of examples describing determination and provision of the residual data as well as corresponding reconstruction of the data.

Referring to an exemplifying data sender 120 according to an example embodiment schematically illustrated in FIG. 3, the first data sender 120 may comprise a data collection portion 310 for obtaining and storing information descriptive of data transmitted by one or more second data senders 140 to the data receiver 160. The data collection portion 310 may be configured to observe or monitor the communication between one or more second data senders 140 and the data receiver 160. The data collection portion 310 may be configured to observe or monitor the data traffic by intercepting data transmitted from a second data sender 140 and to store the intercepted data to one of data buffers 355 dedicated for storing data transmitted by the respective second data sender 140 to the data receiver 160. The data buffers 355 are stored in a memory 350 of the first data sender 120 or in a memory otherwise accessible by the first data sender 120. According to this embodiment, the first data sender 120 monitors the data traffic from a number of second senders 140 and maintains the data buffers 355 for at least one of these second data senders 140. Moreover, the first data sender 120 may be further configured to maintain a data buffer 352 for storing data transmitted from the first data sender 120 itself. Like the data buffers 355, also the data buffer 352 may be stored in the memory 350 of the first data sender 120 or in a memory otherwise accessible by the first data sender 120.

According to an example embodiment, the data collection portion 310 may be configured to continuously observe the data transmitted from the second data senders 140. This approach facilitates detecting data similar to that to be transmitted by the first data sender 120 without support from any external entity and hence without a delay.

Alternatively, the data collection portion 310 may be configured to start and/or stop monitoring of data transmitted from the second data senders 140 in response to a command or instructions to do so. As an example, a user of an apparatus hosting or acting as the first data sender 120 may provide a command to start or stop monitoring the data transmitted by the second data senders 140. As another example, the data receiver 160 receiving data from a number of second data senders 140 may provide a command to start or stop monitoring the data transmitted by the second data senders 140. Such a command originating from the data receiver 160 may further comprise an indication of particular second data senders 140 to be monitored and/or an indication of temporal relationship and/or similarity between data transmitted from the first data source 120 and data transmitted from said particular second data sources 140. This enables e.g. computationally efficient approach where the data collection portion 310 needs only to monitor those second data senders 140 that are likely to transmit data that is similar to that of the first data sender 120. Moreover, in this approach it may not be necessary for the data collection portion 310 to monitor the data transmitted from any of the second data senders 140 unless there is an explicit indication that the data streams from the first data sender 120 and one or more of the second data senders 140 bear some similarities therebetween.

The data collection portion 310 may obtain the data transmitted by a second data sender 140 via a receiver portion of the first data sender 120. The receiver portion may be configured to receive or intercept data and/or signaling information originating from the second data sender 140 and destined to the data receiver 160. The receiver portion may be further configured to make the intercepted data available for the data collection portion 310, e.g. by passing the data to the data collection portion 310 and/or by storing the data in the memory 350, e.g. in the respective data buffer 355, for subsequent access by the data collection portion 310 and/or other portions of the first data sender 120.

The first data sender 120, e.g. data monitoring portion 310, the receiver portion or another portion thereof, may obtain signals transmitted by two or more of the second data senders 140 in as an accumulated signal comprising joint contribution from said two or more second data senders 140. Consequently, the first data sender 120 may be configured to separate the signals transmitted by said two or more second data senders 140 in order to extract respective transmitted data for storage in the data buffers 355. (Blind) signal/source separation techniques known in the art may be employed to extract the data streams provided by the individual second data senders 140 from the accumulated signals, for example the Independent Component Analysis (ICA) described in Hyvärinen A., Karhunen J., Oja E., “Independent Component Analysis”, 2001, John Wiley & Sons, ISBN 0-471-40540-X.

The first data sender 120, e.g. the data monitoring portion 310, may be configured to predict future content of the data buffers 355 on basis of the current content of the data buffers 355. In this regard, the data monitoring portion 310 may be configured to compare the content of the data buffers 355 to a predefined set of reference signals in order to identify a data segment that matches a reference signal or a portion thereof. Consequently, having found a matching reference signal, the monitoring portion 310 may be configured to extend the content of the respective data buffer 355 with subsequent portion(s) of the reference signal, hence predicting the future data for the respective data buffer 355 to make it available as potential reference data that is highly likely to provide a good match with the data to be transmitted from the first data sender 120. As an example in this regard, in case of audio data in a scenario where one or more of the data buffers 355 contain a portion of a song recognized by the data monitoring portion 310 as one of the reference signals, the data monitoring portion may extend the content of the respective data buffers 355 with subsequent portion(s) of the recognized song. As another example regarding the prediction of future content of the data buffers 355 on basis of the current content of the data buffers 355, the first data sender 120 may be configured to apply prediction techniques known in the art, such as logistic regression, to predict upcoming data of one or more of the data buffers 355 on basis of the current and/or past data of the respective data buffers 355.

According to an example embodiment, the first data sender 120 may further comprise a data comparison portion 320 for determination of reference data in order to subsequently transmit data with a reference to the reference data. The data comparison portion 320 may be configured to access the one or more data buffers 355 and to identify reference data in one of said data buffers 355. The reference data in the data buffers 355 may be identified on basis of the data to be transmitted by the first data sender 120 e.g. by searching across the data buffers 355 to identify data block or data segment fulfilling predetermined criteria with respect to level of similarity with the data block to be transmitted. As an example, such criteria may require the reference data to be an exact copy of the data to be transmitted. As another example, the criteria may require finding reference data to be data of the data buffers 355 that is most similar to the data to be transmitted in accordance with a predefined similarity function, thereby not necessarily resulting in the reference data being an exact copy of the data to be transmitted. Such a similarity function may, for example, attempt to find a data block of the data buffers 355 that exhibits the smallest difference to the data to be transmitted e.g. by minimizing a mean absolute error (MAE) or a mean squared error (MSE). Alternatively, the similarity function may be arranged to determine a data block of the data buffers 355 that maximizes correlation with the data to be transmitted.

As a further example, the similarity function may be employed to find a data block exhibiting characteristics that are most similar to respective characteristics of the data to be transmitted. Such characteristics may be extracted e.g. by applying a predetermined function or processing rule both to the candidate data blocks stored in the data buffers 355 and to the data to be transmitted. For example in case of media data such as audio data or video data such a similarity function may be configured to search for a data block that is perceptually (most) similar to the data block to be transmitted. Similarity functions of such type are known in the art. A particular example in this regard is a similarity function arranged to evaluate perceptual difference between to segments of audio data, e.g. the one described in F. Kurth, “Efficient Index-Based Audio Matching”, IEEE Transactions on Audio, Speech and Language Processing, vol. 16, Issue 2, pp. 385-395, 2008.

An output of the data comparison portion 320 may comprise an indication of the identified reference data in the data buffers 355. The indication may comprise an indicator identifying the reference source and/or the data buffer of the one or more data buffers 355 that corresponds to the reference source. The indication may further comprise an indicator referring to the location of the reference data in the data buffer corresponding to the reference source. Alternatively or additionally, an output of the data comparison portion 320 may comprise the reference data as extracted from the data buffers 355 or otherwise reconstructed on basis of the information stored in the data buffers 355 e.g. to facilitate a data reduction portion 330 determining the residual data, as described in more detail hereinafter.

According to an example embodiment, the data comparison portion 320 may be configured to identify, indicate and/or extract the reference data regardless of the level of similarity indicated by the applied similarity function. According to another example embodiment, the data comparison portion 320 may be configured to identify, indicate and/or extract the reference data only in case the applied similarity function indicates level of similarity reaching or exceeding a predetermined similarity threshold. In contrast, in response to level of similarity failing to reach said predetermined similarity threshold, the data comparison portion 320 may be configured to output an indication regarding the failure to identify reference data meeting the criteria with respect to the similarity with the data to be transmitted from the first data source 120 in the data buffers 355.

In an example embodiment, instead of directly searching for the reference data across the one or more data buffers 355, the data comparison portion 320 may be configured to access the one or more data buffers 355 to identify a reference source on basis of the data that has been transmitted and/or that is to be transmitted from the first data source 120 and on basis of the data stored in the data buffers 355. This identification may involve using one or more blocks or segments of data from the data buffer 352 storing data transmitted from the first data sender 120 to the data receiver 160 and identifying a data buffer of the data buffers 355 storing data that is most similar to said one or more blocks or segments of data from the data buffer 352 in accordance with a predetermined similarity function. The similarity function may be similar to that described hereinbefore. In addition to or instead of considering one or more blocks or segments of data of the data buffer 352, the search for the reference source may consider the data block to be transmitted from the first data source 120. Once the data buffer 355 indicating the highest level of similarity with the data (to be) transmitted from the first data source 120 has been identified, the second data sender 140 corresponding to this data buffer 355 is chosen as the reference source. Consequently, the reference data is searched in the data buffer 355 corresponding to the reference source only. The selected reference source may be applied e.g. for a predetermined period of time, after which a new identification of the reference source may be carried out. Alternatively or additionally, a new identification of the reference source may be carried out, for example, in response to a failure to identify reference data exhibiting required level of similarity in the data buffer corresponding to the reference source for a predetermined number of successive searches.

According to an example embodiment, the first data sender 120 may further comprise the data reduction portion 330 for reducing the data to be transmitted from the first data source 120 to the data receiver 160. The data reduction portion 330 may be configured to determine and/or derive residual data descriptive of the data to be transmitted in relation to the reference data. The residual data may comprise, for example difference data indicative of the difference between the data to be transmitted and the reference data. Such difference data may be determined/derived e.g. as a direct subtraction of the values of the respective data elements of the reference data and the data to be transmitted. Consequently, the residual data comprises information that enables reconstruction of the data in the receiving end, e.g. at the data receiver 160 as the sum of the residual data and the reference data.

In order to enable successful reconstruction in the receiving end, the residual data may further comprise information that identifies the reference data. As described hereinbefore in context of the exemplifying output of the data comparison portion 320, such identification data may comprise an indication identifying the reference source or the data buffer 355 that corresponds to the reference source and/or an indication referring to the location of the reference data in the data buffer 355 corresponding to the reference source. Depending on the extent of knowledge shared between the first data source 120 and the data receiver 160 and depending on the number of data buffers 355 considered in the identification of the reference data and/or reference source, the data receiver 160 may be aware of the reference source without an explicit indication thereto and hence it may not be necessary to provide this information as part of the residual data.

While in general case the received data is preferably an exact copy of the data (to be) transmitted, for some types of data the received data does not have to be an exact copy of the source data but data approximating the data to be transmitted may suffice. The sensory data, the audio data and the video data used as examples hereinbefore serve as examples of data of such type. For such a scenario it may not be necessary to transmit the difference data at all but it sufficient to provide an indication of the reference data directly replacing the data to be transmitted. In this regard, the data reduction portion 330 may be configured to always provide an indication of the reference data directly replacing the data to be transmitted without further assessment of the difference therebetween, thereby enabling the reconstruction an approximation of the data to be transmitted in the data receiver 160 solely on basis of the indication identifying the reference data.

As a variation of this example, the data reduction portion 330 may be configured to apply a predetermined criterion to assess whether the difference between reference data and the data to be transmitted is small enough to justify complete omission of the difference data from the residual data. Consequently, in case the difference is small enough only an indication of the reference data is provided, whereas in case the difference not being small enough the indication of the reference data is provided together with the difference data indicative of the difference between the data to be transmitted and the reference data.

As another variation of the examples above, the difference data may be provided regardless of the extent of difference between reference data and the data to be transmitted or in response to the difference exceeding a predetermined threshold, but difference data does not necessarily fully describe the difference between the reference data and the data to be transmitted but rather provides complementary data to enable keeping the reconstruction error in the data receiver 160 at a small enough level. A benefit of such kind of difference data is that it may enable significantly lower data rate than difference data providing full description of the difference between reference data and the data to be transmitted while keeping the perceived quality of the reconstructed data in the data receiver 160 at a sufficient level.

On the other hand, in response to the data comparison portion 320 indicating a failure to identify reference data meeting the criteria with respect to the similarity with the data to be transmitted from the first data source 120, the data reduction portion 330 may be configured to provide the original data to be transmitted as such as the residual data, possibly accompanied by an indication in this regard to enable the data receiver 160 to distinguish such ‘unreduced data’ from the reduced data transmitted in response to successful identification of the reference data in the data buffers 355.

In accordance with an example embodiment, the data source 120 may comprise a data transmission portion 340. The data transmission portion 340 may be configured to provide the residual data provided by the data reduction portion 330 for transmission to the data receiver 160. The provision for transmission may comprise e.g. storing the residual data into the memory 350 or to a memory otherwise accessible by the first data sender 120 to enable transmission of the residual data over a network by a transmitter portion provided at or accessible by the first data source 120. Instead of storing the residual data to the memory 350 for the transmitter portion to access, the data transmission portion 340 may be configured to directly pass the residual data to the transmitter portion. Hence, the data transmission portion 340 rather facilitates the actual transmission of the residual data for transmission over the network than actually performs the transmission—which is typically carried out by a dedicated transmitter portion, such as a transceiver capable of wireless transmission at radio frequencies using a cellular or WLAN protocol and/or a network card or network interface capable of communication over a network using Ethernet standards. Alternatively, the data transmission portion 340 may comprise the transmitter portion, e.g. one of the transmitters exemplified hereinbefore.

Consequently, the data receiver 160 may be configured, e.g. upon receiving the residual data from the first data sender 120, to reconstruct the data at least on basis of the residual data by accessing the data buffers 452, 455 to obtain the reference data indicated in the residual data. The data receiver 160 may be further configured to apply the difference data possibly included in the residual data and derive the reconstructed data as a combination of the reference data and the difference data, e.g. as a sum of the corresponding elements of the reference data and difference data.

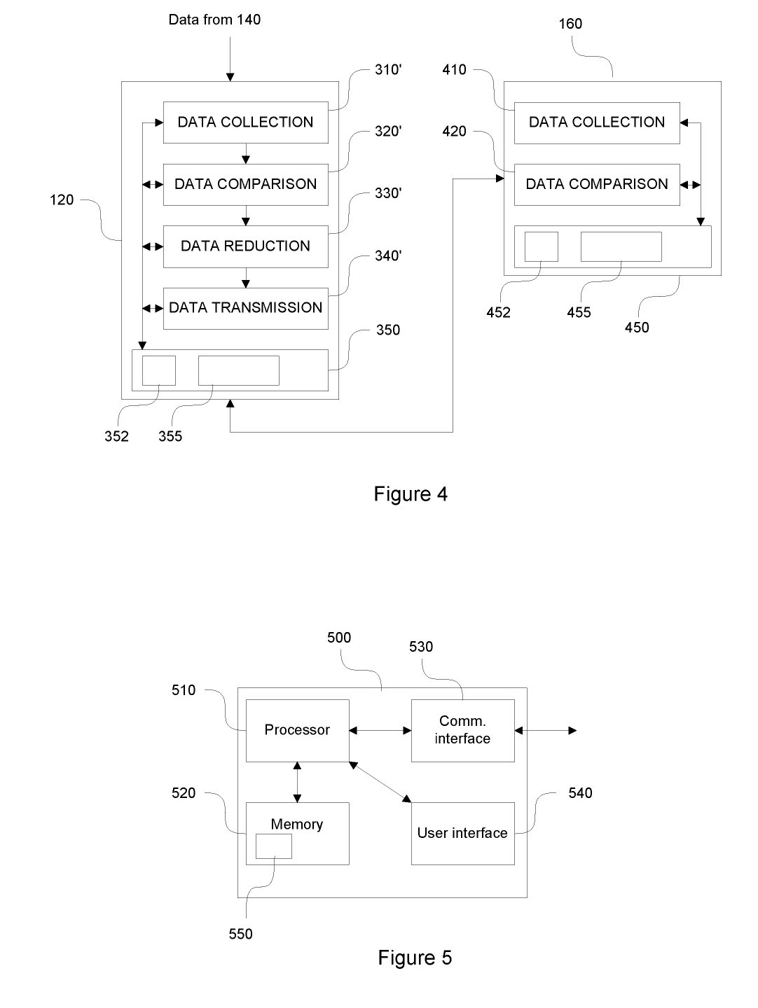

Instead of or in addition to the data collection portion 310 of the first data sender 120 actively monitoring the data transmitted by the second data senders 140, in an example embodiment the data receiver 160 may comprise a data collection portion 410 for obtaining and storing information descriptive of data transmitted from one or more second data senders 140 to the data receiver 160, as schematically illustrated in FIG. 4. The data collection portion 410 may be further configured to store data received from the first data source 120. The data collection portion 410 may be configured store the data received from the first data sender 120 in data buffer 452 and to store the data received from the second data senders 140 in respective data buffers 455. The data buffers 452, 455 are stored in a memory 450 of the data receiver 160 or in a memory otherwise accessible by the data receiver 160.

According to an example embodiment, the data receiver 160 may further comprise a data comparison portion 420 for facilitating determination of reference data in order to enable the first data sender 120 to subsequently transmit data with a reference to the reference data. The data comparison portion 420 may be configured to identify the reference source on basis of the data received from the first data sender 120 stored in the data buffer 452 and on basis of the data received from the second data senders 140 stored in the data buffers 455. The identification of the reference source may be performed in a manner similar to that described in context of the data comparison portion 320, the data buffer 352 and the data buffers 355. Hence, an output of the data comparison portion 420 may comprise an indicator identifying the reference source and/or the data buffer of the data buffers 455 that corresponds to the reference source. The data comparison portion 420 may be configured to provide, e.g. send, the indicator identifying the reference source to the first data sender 120 to enable determination or identification of the second data source 140 selected as the reference source. The indication provided to the first data source 120 may further comprise information indicating alignment between the received from the first data source 120 and the data received from the second data source 140 identified as the reference source. Such alignment information may comprise e.g. an indication of temporal alignment between the data streams as stored in the respective data buffers 452, 455 and hence in the data buffers 352, 355.

The data comparison portion 420 may be further configured, e.g. as part of the process of identifying the reference source, to identify one or more second data senders 140 that are transmitting data that exhibits similarity to the data received from the first data sender 120. This may involve, for example, identifying the second data senders 140 that are transmitting data whose similarity exceeds a predefined similarity threshold according to a predetermined similarity function or similarity measure. Such similarity function/measure may be based on e.g. MAE, MSE, correlation, and/or perceptual criteria, as described hereinbefore in context of the data comparison portion 320. Consequently, the data comparison portion 420 may be configured to provide the first data sender 120 with indication of the second data senders 140 transmitting data exhibiting sufficient level of similarity with that of the first data sender 120. This enables the first data sender 120 to monitor only those second data senders 140 in its vicinity that are likely to provide data that is similar to the data (to be) transmitted by the first data sender 120.

In parallel, the data collection portion 310′ of first data source 120 may be configured to observe or monitor the communication between one or more second data senders 140 and the data receiver 160 and store the data transmitted from a second data sender 140 and to store the intercepted data into the one of data buffers 355, as described hereinbefore in context of the data collection portion 310. Upon receiving the indication identifying the reference source from the data receiver 160, the data comparison portion 320′ may be configured to identify the reference data on basis of the data to be transmitted from the first data source 120 to the data receiver 160 and on basis of the information stored in the data buffer 355 corresponding to the reference source, as described hereinbefore in context of the data comparison portion 320. This approach assigns at least part of the computational load involved in identifying the reference data to the data receiver 160 instead of the first data sender 120. Alternatively, the data collection portion 310′ may be configured to observe or monitor the communication only from the second data source 140 acting as the reference source and, consequently, to only maintain the data buffer 355 corresponding to the respective second data source 140. This approach may further reduce the computational burden of the first data source 120.

Hence, an output of the data comparison portion 320′ comprises an indication of the identified reference data in the data buffers 355. The indication may comprise an indicator identifying the reference source and/or the data buffer 355 that corresponds to the reference source. The indication may further comprise an indicator referring to the location of the reference data in the data buffer 355 corresponding to the reference source. Alternatively or additionally, an output of the data comparison portion 320′ may comprise the reference data as extracted from the data buffers 355 or otherwise reconstructed on basis of the information stored in the data buffers 355.

Along the lines described in context of the data comparison portion 320, the data comparison portion 320′ may be configured to identify, indicate and/or extract the reference data in the data buffer 355 corresponding to the reference source regardless of the level of similarity indicated by the applied similarity function. Alternatively, the data comparison portion 320′ may be configured to indicate and/or extract the reference data in the data buffer 355 corresponding to the reference source only in case the applied similarity function indicates level of similarity exceeding a predetermined similarity threshold.

According to an example embodiment, the data reduction portion 330′ and the data transmission portion 340′ are identical to the data reduction portion 330 and the data transmission portion 340, respectively, described hereinbefore.

The data is, preferably but not necessarily, transmitted from the data senders 120, 140 to the data receiver 160 in blocks. Depending on a type of data, a block of data may employ fixed size (expressed e.g. in bytes and/or bits), the transmitted/received data stream hence comprising a plurality of data blocks of equal size. Alternatively, the size of the data blocks may vary from to block to block, thereby resulting in a data stream comprising a plurality of data blocks exhibiting different sizes. Consequently, the data comparison portion 320, 320′, 420, the data reduction portion 330, 330′ and the data transmission portion 340, 340′ may be configured to process the received and/or transmitted data as blocks of corresponding size.

A data buffer of the one or more data buffers 355, 455 may be arranged to store data transmitted by the respective one or more second data sources 140 such that a predetermined period of duration, expressed e.g. in hours, minutes, seconds and/or fractions thereof, of data most recently transmitted/received from the respective second data source 140 is covered. Alternatively, as a second example in this regard, a data buffer of the one or more data buffers 355, 455 may be arranged to store data transmitted by the respective one or more second data sources 140 such that a predetermined number of bytes and/or bits of data most recently transmitted/received from the respective second data source 140 is covered. As a further example, a data buffer of the one or more data buffers 355, 455 may be arranged to store a predetermined number of data blocks, e.g. data packets, most recently transmitted/received from the respective one or more second data sources 140. The data buffers 352, 452 for storing the data transmitted by the first data sender 120 may be arranged to store the data in a manner similar to corresponding data buffers 355, 455. The data buffers 352, 355, 452, 455 preferably operate according to the first in first out (FIFO) principle, i.e. upon storing new data in a buffer the oldest data in the buffer is removed to make way for the new data.

A data buffer 352, 355, 452, 455 may be configured to store the data with time stamps or other indicators suitable for indicating the temporal relationships between the data stored in the buffers 352, 355, 452, 455. Such time stamps may be received together with the data transmitted from the respective second data sender 140 or derived on basis of information transmitted within or together with the data transmitted from the respective second data sender 140. A time stamp may be provided e.g. with each block of data stored in the data buffer. The time stamps of the data streams may be readily synchronized to a common clock and hence directly serve as indicators descriptive of the temporal alignment between the data stored in the data buffers 352, 355, 452, 455. Alternatively, the time stamps of a data stream may exhibit random values with respect to time stamps of the other data streams and hence exhibit static or essentially static difference to the corresponding time stamps of the other data streams. Instead of relying on time stamps received together with the data, e.g. data collection portion 310, 310′ may be configured to provide the data stored in the data buffers 352, 355 with time stamps according to a local clock to enable subsequent identification of temporal relationship between the data stored in the data buffers 352, 355. Similarly, the data collection portion 410 may be configured to store data into the data buffers 452, 455 with locally generated time stamps. Instead of time stamps, other suitable identifiers e.g. block numbers or block identifiers of other type, received together with the data or generated locally upon reception may be employed to enable identification of temporal relationship between the data stored in the data buffers 352, 355, 452, 455. A non-limiting example of a data transport protocol providing both time stamps and sequence numbers is the Real-time Transport Protocol (RTP) specified in the Internet Engineering Task Force (IETF) Request For Comments 3550 (RFC 3550). A non-limiting example of a protocol that enables synchronization of data originating from separate sources is the Network Time Protocol (NTP) specified in the IETF RFC 5905.

In the following, a non-limiting example describing an example embodiment for handing audio data is provided to further illustrate the concepts of the present invention described hereinbefore in more general terms in context of the data senders 120, 140, the data receiver 160 and the data collection portions 310, 410, the data comparison portions 320, 420, the data reduction portions 330, 330′ and/or the data transmission portions 340, 340′.

According to an example scenario, the first data sender 120 may be configured to capture audio signal from an audio source in its vicinity, to process the captured audio signal and to transmit the processed audio signal to the data receiver 160. The first data sender 120 is further configured to store the audio signal it transmits, either the captured one or the processed one, in the data buffer 352. Moreover, there may be a number of second data senders 140 also configured to capture the audio signal from the same audio source, to process respective captured audio signals and to provide the respective processed audio signals to the data receiver 160. The first data sender 120 is further configured to receive/intercept the audio data transmitted from the second data senders 140 and store the respective audio data into the data buffers 355. In parallel, the data receiver 160 is configured to receive the audio data from the data senders 120, 140 and to store the received audio data in the respective data buffers 452, 455 at the data receiver 160.

Upon transmitting an input audio data block A(i) the first data sender 120 is configured to determine the reference audio data corresponding to the input audio data block A(i) in the data buffers 355. The data buffers 355 may include, for example, buffers B, C and E for storing audio data transmitted from the respective second data senders 140. As described hereinbefore, this may involve determining the reference audio data block R(i) in the audio data stored in the data buffers 355 providing the best match with the input audio data block A(i). In this example the information identifying the reference audio data block R(i), to be provided to the data receiver 160 in the residual data, may comprise an indication regarding which of the buffers B, C and E stores the reference audio data block R(i) together with information indicating the location in the reference buffer B/C/E storing the reference audio data block R(i). The information indicating the location within a buffer may be e.g. an offset-indicator indicative of (temporal) offset from a reference point, e.g. from a point of the respective buffer (temporally) correspond to the beginning of the input audio data block A(i).

Instead of considering the audio data transmitted from the data senders 120, 140 to the data receiver 160 as a whole, the determination of the reference audio data block R(i) may involve consideration of only certain components of the audio data, e.g. certain frequency components and/or certain frequency band(s) of the audio data. As an example, such frequency components/bands may be the ones considered perceptually most important. Consequently, the first data sender 120 selects the reference audio data block R(i) such that the frequency components/bands of interest exhibit maximal similarity to the corresponding frequency components/bands of the input audio data block A(i) among the data blocks stored in the data buffers 355.

Once the reference audio data block R(i) has been identified, the first data sender 120 may be configured to compute the difference audio data block D(i)=R(i)−A(i) and to provide the difference audio data block D(i) together with information identifying the reference audio data block R(i) in the data buffers 355, 455 for transmission to the data receiver 160 as the residual data corresponding to the data block i. The data receiver 160 is configured to apply the residual data to derive a reconstructed audio data block A′(i)=R(i)+D(i). In case the difference audio data block D(i) fully describes the difference between the data blocks A(i) and R(i), the reconstructed audio data block A′(i) is an exact copy of the input audio data block A(i), i.e. A′(i)=A(i). However, as described hereinbefore, the difference audio data may be difference data D′(i) that does not fully describe the difference between the data blocks A(i) and R(i) but describes the difference accurately enough to ensure that the reconstructed audio data block A″(i)=R(i)+D′(i) represents the input audio data block A(i) at a sufficient perceptual quality. As another example of non-perfect reconstruction at the data receiver 160, as also described hereinbefore, the residual data may not provide the difference audio data at all and hence the reconstructed audio data may be formed on basis of the reference audio data as A″(i)=R(i).

In case the audio data transmitted from the data senders 120, 140 is encoded, the first data sender 120 is preferably configured to decode the audio data received from the second senders 140 before storing it into the data buffers 355. Consequently, the first data sender 120 may be further configured to encode the difference audio data block D(i) or D′(i) prior to provision for transmission to the data receiver 160. The data receiver 160, in turn, decodes the difference audio data block D(i) or D′(i) into a decoded difference audio data block before forming the reconstructed audio data block A″(i) as a sum of the reference audio data R(i) and the decoded difference audio data block.

In some scenarios the audio data (as well as data of any other type) transmitted from the data senders 120, 140 to the data receiver 160 may be encrypted. Consequently, in order to enable making use of the encrypted audio data transmitted from the second data senders 140 the first data sender 120 may be configured to decrypt the intercepted encrypted audio data as transmitted from the second data senders 140. Moreover, the first data sender 120 may be configured to (re-)encrypt e.g. the difference audio data D(i) or D′(i) possibly provided for transmission as part of the residual data to the data receiver 160. The first data sender 120 and the second data senders 140 may employ a pre-shared encryption key to enable the first data sender 120 to decrypt encrypted audio data originating from the second data senders 140 and to (re-)encrypt audio data transmitted from the first data sender 120. Instead of applying a pre-shared encryption key, the first data sender 120 and the second data sender 140 may carry out signaling to exchange encryption key(s) that enable the first data sender 120 decrypting and decrypting the audio data. The encryption key(s) so exchanged may enable the first data sender to decrypt all data transmitted from the second data senders 140 or the encryption keys so exchanged may be dedicated to the audio data only, hence enabling the first data sender 120 to decrypt only the audio data or certain audio data streams transmitted from the second data senders 140 while the other data transmitted from the second data senders 140 is encrypted using a different security mechanism and/or a different encryption key hence making it inaccessible by the first data sender 120.

The operations, procedures, functions and/or methods described in context of the first data sender 120, the second data senders 140 and the data receiver 160 may be provided as means for carrying out the corresponding operations, procedures, functions and/or method steps assigned to the above-mentioned entities. Such means may be provided as software means, as hardware means, or as a combination of software means and hardware means.

As an example, the first data sender 120 may be provided as an apparatus comprising means for storing, in the one or more data buffers 352, 355, information descriptive of data transmitted from respective one or more data senders 120, 140 to a destination, means for identifying reference data in said one or more data buffers 355 on basis of data to be transmitted by the first data sender 120 and on basis of information stored in said one or more data buffers 352, 355, means for determining residual data descriptive of the data to be transmitted by the first data sender 120 in relation to the said reference data and means for means for transmitting the residual data to the data receiver 160.

The means for identifying reference data may comprise means for identifying a reference source and means for identifying the reference data in the data buffer corresponding to the reference source. The means for identifying a reference source may comprise means for identifying a reference source on basis of data transmitted from the first data sender 120 and on basis of information stored in said one or more data buffers 355, or the means for identifying a reference source may comprise means for means for receiving an indication identifying the reference source from the data receiver 160.

The means for identifying reference data may comprise means for applying a predetermined similarity function to identify the reference data. As described hereinbefore in context of the data comparison portion 320, 320′, such a similarity function may be arranged, as described hereinbefore, to identify a data segment of said one or more data buffers 355 that exhibits smallest difference to the data to be transmitted and/or a data segment that exhibits highest correlation with the data to be transmitted. Alternatively, such a similarity function may be arranged to apply a predetermined processing rule to extract characteristics of data and arranged to identify a data segment of said one or more data buffers 355 that exhibits characteristics most similar to those of the data to be transmitted. Moreover, as described hereinbefore in context of the data comparison portion 320, 320′, the means for identifying reference data may comprise means for identifying reference data only in response to the similarity function indicating level of similarity exceeding a predetermined similarity threshold.

FIG. 5 schematically illustrates an exemplifying apparatus 500 upon which an embodiment of the invention may be implemented. The apparatus 500 as illustrated in FIG. 5 provides a diagram of exemplary components of an apparatus, which is capable of operating as or providing the first data sender 120, the second data sender 140 or the data receiver 160 in the example arrangement 100 of FIG. 1 according to an example embodiment. The apparatus 500 comprises a processor 510, a memory 520 and a communication interface 530, such as a network card or a network adapter enabling wireless or wireline communication with another apparatus and/or radio transceiver enabling wireless communication with another apparatus over radio frequencies. The processor 510 is configured to read from and write to the memory 520. The apparatus 500 may further comprise a user interface 540 for providing data, commands and/or other input to the processor 510 and/or for receiving data or other output from the processor 510, the user interface 540 comprising for example one or more of a display, a keyboard or keys, a mouse or a respective pointing device, a touchscreen, a touchpad, etc. The apparatus 500 may comprise further components not illustrated in the example of FIG. 5.

Although the processor 510 is presented in the example of FIG. 5 as a single component, the processor 510 may be implemented as one or more separate components. Although the memory 520 in the example of FIG. 5 is illustrated as a single component, the memory 520 may be implemented as one or more separate components, some or all of which may be integrated/removable and/or may provide permanent/semi-permanent/dynamic/cached storage.

The apparatus 500 may be embodied for example as a mobile phone, a digital camera, a digital video camera, a music player, a gaming device, a laptop computer, a desktop computer, a personal digital assistant (PDA), an internet tablet, a television set, etc.—basically as any apparatus that is able to communicate with another apparatuses or that may be (re-)configured to be able to communicate with another apparatuses.

The memory 520 may store a computer program 550 comprising computer-executable instructions that control the operation of the apparatus 500 when loaded into the processor 510. As an example, the computer program 550 may include one or more sequences of one or more instructions. The computer program 550 may be provided as a computer program code. The processor 510 is able to load and execute the computer program 550 by reading the one or more sequences of one or more instructions included therein from the memory 520. The one or more sequences of one or more instructions may be configured to, when executed by one or more processors, cause an apparatus, for example the apparatus 500, to implement the operations, procedures and/or functions described hereinbefore in context of the first data sender 120, the second data sender 140 or the data receiver 160.

Hence, the apparatus 500 may comprise at least one processor 510 and at least one memory 520 including computer program code for one or more programs, the at least one memory 520 and the computer program code configured to, with the at least one processor 510, cause the apparatus 500 to perform the operations, procedures and/or functions described hereinbefore in context of the first data sender 120, the second data sender 140 or the data receiver 160.

The computer program 550 may be provided at the apparatus 500 via any suitable delivery mechanism. As an example, the delivery mechanism may comprise at least one computer readable non-transitory medium having program code stored thereon, the program code which when executed by an apparatus cause the apparatus at least implement processing to carry out the operations, procedures and/or functions described hereinbefore in context of the first data sender 120, the second data sender 140 or the data receiver 160. The delivery mechanism may be for example a computer readable storage medium, a computer program product, a memory device a record medium such as a CD-ROM or DVD, an article of manufacture that tangibly embodies the computer program 550. As a further example, the delivery mechanism may be a signal configured to reliably transfer the computer program 550.

Reference to a processor should not be understood to encompass only programmable processors, but also dedicated circuits such as field-programmable gate arrays (FPGA), application specific circuits (ASIC), signal processors, etc. Features described in the preceding description may be used in combinations other than the combinations explicitly described. Although functions have been described with reference to certain features, those functions may be performable by other features whether described or not. Although features have been described with reference to certain embodiments, those features may also be present in other embodiments whether described or not.

1-80. (canceled)

81. An apparatus comprising at least one processor and at least one memory including computer program code for one or more programs, the at least one memory and the computer program code configured to, with the at least one processor, cause the apparatus to perform at least the following:
store, in one or more data buffers, information descriptive of data transmitted from respective one or more data sources to a destination,
identify reference data in said one or more data buffers on basis of data to be transmitted by the apparatus and on basis of information stored in said one or more data buffers,
determine residual data descriptive of the data to be transmitted by the apparatus in relation to the said reference data, and
transmit the residual data to the destination.

82. An apparatus according to claim 81, wherein identifying reference data comprises identifying a reference source and to identify the reference data in the data buffer corresponding to the reference source.

83. An apparatus according to claim 82, wherein identifying reference data comprises identifying the reference source on basis of data transmitted from the apparatus and on basis of information stored in said one or more data buffers.

84. An apparatus according to claim 82, wherein identifying reference data comprises receiving, from the destination, an indication identifying the reference source.

85. An apparatus according to claim 82, wherein identification of the reference source is based on a predetermined similarity function arranged to identify a data buffer of said one or more data buffers storing data that exhibits smallest difference to and/or that exhibits highest correlation with the data transmitted from the apparatus.

86. An apparatus according to claim 82, wherein identification of the reference source is based on a predetermined similarity function configured to apply a predetermined processing rule to extract characteristics of data and arranged to identify a data buffer of said one or more data buffers storing data that exhibits characteristics most similar to those of the data transmitted from the apparatus.

87. An apparatus according to claim 81, wherein identification of the reference data is based on a predetermined similarity function arranged to identify a data segment of said one or more data buffers that exhibits smallest difference to the data to be transmitted and/or that exhibits highest correlation with the data to be transmitted.

88. An apparatus according to claim 81, wherein identification of the reference data is based on a predetermined similarity function configured to apply a predetermined processing rule to extract characteristics of data and arranged to identify a data segment of said one or more data buffers that exhibits characteristics most similar to those of the data to be transmitted.

89. An apparatus according to claim 87, wherein reference data is identified only in response to the similarity function indicating level of similarity exceeding a predetermined similarity threshold.

90. An apparatus according to claim 81, wherein the residual data comprises an indication of the location of the reference data in the one or more data buffers.

91. An apparatus according to claim 90, wherein the residual data comprises difference data descriptive of the difference between the data to be transmitted and the reference data.

92. An apparatus according to claim 90, wherein the residual data comprises an indication of the reference data replacing the data to be transmitted.

93. An apparatus according to claim 81, wherein the data is audio data.

94. A method comprising
storing, in one or more data buffers, information descriptive of data transmitted from respective one or more data sources to a destination,
identifying reference data in said one or more data buffers on basis of data to be transmitted by an apparatus and on basis of information stored in said one or more data buffers,
determining residual data descriptive of the data to be transmitted by the apparatus in relation to the said reference data, and
transmitting the residual data to the destination.

95. A method according to claim 94, wherein identifying reference data comprises identifying a reference source and to identify the reference data in the data buffer corresponding to the reference source.

96. A method according to claim 95, wherein identifying reference data comprises identifying the reference source on basis of data transmitted from the apparatus and on basis of information stored in said one or more data buffers.

97. A method according to claim 95, wherein identifying reference data comprises receiving, from the destination, an indication identifying the reference source.

98. A method according to claim 95, wherein identification of the reference source is based on a predetermined similarity function arranged to identify a data buffer of said one or more data buffers storing data that exhibits smallest difference to or that exhibits highest correlation with the data transmitted from the apparatus.

99. A method according to claim 95, wherein identification of the reference source is based on a predetermined similarity function configured to apply a predetermined processing rule to extract characteristics of data and arranged to identify a data buffer of said one or more data buffers storing data that exhibits characteristics most similar to those of the data transmitted from the apparatus.

100. A computer program product comprising at least one computer readable non-transitory medium having program code stored thereon, the program which when executed by an apparatus cause the apparatus at least to
store, in one or more data buffers, information descriptive of data transmitted from respective one or more data sources to a destination,
identify reference data in said one or more data buffers on basis of data to be transmitted by the apparatus and on basis of information stored in said one or more data buffers,
determine residual data descriptive of the data to be transmitted by the apparatus in relation to the said reference data, and
transmit the residual data to the destination.
